(19) United States
(12) Patent Application Publication
(10) Pub. No.: US 2006/0133126 A1
(43) Pub. Date: Jun. 22, 2006

(54) Semiconductor memory device capable of switching from multiplex method to non-multiplex method

(75) Inventors: Tomoyuki Fujisawa, Tokyo (JP); Takashi Kubo, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/268,581

(22) Filed: Nov. 8, 2005

(30) Foreign Application Priority Data
Dec. 22, 2004 (JP) 2004-371823

(51) Int. Cl. G11C 5/06

(52) U.S. Cl. 365/63

(57) ABSTRACT

There is provided a semiconductor memory device which adopts a multiplex method in which an address signal and a data signal are input into the same terminal, and which is capable of switching from the multiplex method to a non-multiplex method in which an address signal and a data signal are respectively input into separate terminals. The semiconductor memory device is provided with an address pad into which only an address signal is input, independently of an address data multipad into which an address signal and a data signal are input. A switching control signal generated in the multiplex method/non-multiplex method is used to switch the paths of the address signal input into an address buffer. Accordingly, it is possible to input an address signal and a data signal into the address buffer and a data buffer, respectively, in parallel.

### BACKGROUND OF THE INVENTION

1. Field of the Invention

The present invention relates to a semiconductor memory device, and more particularly, to a semiconductor memory device capable of switching between a multiplex method and a non-multiplex method.

2. Description of the Background Art

In recent years, a technique of forming a minute semiconductor integrated circuit and a technique of increasing the packing density of a semiconductor integrated circuit have made remarkable progress, and thus, a memory device has achieved significantly large storage capacity and large scale. Since the number of bits to be processed is increased accordingly, the number of terminals required for serving as address terminals and data input/output terminals, for example, tends to increase.

Conventionally, there has been adopted a technique of employing a multiplex method, for example, to share terminals and others so that increase in number of terminals can be prevented.

Japanese Patent Laying-Open No. 11-306796 discloses an address multiplex method and a semiconductor memory device in which an address terminal is shared between a column side and a row side in a time-sharing manner. This document also discloses a configuration of a semiconductor memory device in which a number of address terminals used by a tester is reduced and an address is input into a terminal in a time-sharing manner so that a test can efficiently be conducted without increasing the number of terminals used by the tester.

In contrast, Japanese Patent Laying-Open No. 09-073772 discloses a semiconductor memory device employing a multiplex method in which a terminal is shared for serving as an address terminal and a data input/output terminal, instead of the multiplex method in which an address terminal is shared between a column side and a row side, so that increase in number of terminals can be prevented.

However, in the semiconductor memory device adopting the multiplex method in which a terminal is shared for serving as an address terminal and a data input/output terminal, as disclosed in the above-described document, the types of information handled by an address signal and a data signal are totally different although these signals share a terminal. Therefore, when the semiconductor memory device is subjected to a wafer test, for example, an external command system becomes remarkably complex when compared with a conventional semiconductor memory device adopting a method other than a multiplex method (hereinafter also referred to as a non-multiplex method). As a result, it is necessary to provide in a tester a test program and a test jig totally different from those for the semiconductor memory device adopting a non-multiplex method. In other words, the semiconductor memory device adopting a multiplex method cannot use a tester designed for a conventional semiconductor memory device adopting a non-multiplex method. Therefore, if a multiplex method is adopted, the cost of the tester becomes extremely high, which inevitably causes considerable increase in cost of the test.

### SUMMARY OF THE INVENTION

The present invention is made to solve the problems above. An object of the present invention is to provide a semiconductor memory device which adopts a multiplex method to share a terminal for use as an address terminal and a data input/output terminal, and which is capable of switching from the multiplex method to a non-multiplex method.

A semiconductor memory device according to the present invention includes: a memory array having a plurality of memory cells integrally arranged in matrix; an interface circuit for sending and receiving a signal to and from an outside; a multipad used in sending and receiving an output and an input of each of an address signal and a data signal between the interface circuit and the outside in a first mode; an address selection circuit for accessing a selected memory cell in the memory array based on the address signal input into the interface circuit; and an address pad having the address signal input thereinto in a second mode independently of the multipad. The interface circuit includes a switching circuit for connecting the multipad and the address selection circuit in the first mode, and connecting the address pad and the address selection circuit in the second mode.

The semiconductor memory device according to the present invention is provided with an address pad having an address signal input thereinto in a second mode, independently of a multipad used in sending and receiving an output and an input of each of an address signal and a data signal in a first mode, and includes a switching circuit for switching between a connection of the multipad with an address selection circuit and a connection of the address pad with the address selection circuit. Accordingly, it is possible to easily modify the design depending on a user's demand. When a tester is used for a test, for example, a test can be conducted by using a low-cost tester for the test.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is schematic block diagram of a semiconductor memory device according to embodiments of the present invention.

FIG. 2 is a circuit configuration diagram of an address buffer according to a first embodiment of the present invention.

FIG. 3 is a diagram for describing a signal generating portion and a part of a data buffer according to the first embodiment of the present invention.

FIG. 4 is a circuit configuration diagram of a switching control signal generating circuit according to the first embodiment of the present invention.

FIGS. 5A and 5B are waveform diagrams for operations in a non A/D-MUX mode.

FIGS. 6A and 6B are waveform diagrams for operations in an A/D-MUX mode.

FIG. 7 is a circuit configuration diagram of a switching control signal generating circuit according to a second embodiment of the present invention.

FIG. 8 is a schematic diagram of a PROM embedded in a semiconductor memory device according to the second embodiment of the present invention.

### DESCRIPTION OF THE PREFERRED EMBODIMENTS

Embodiments of the present invention will now be described in detail with reference to the drawings. The same or corresponding portions are indicated by the same reference characters, and the description thereof will not be repeated.

### First Embodiment

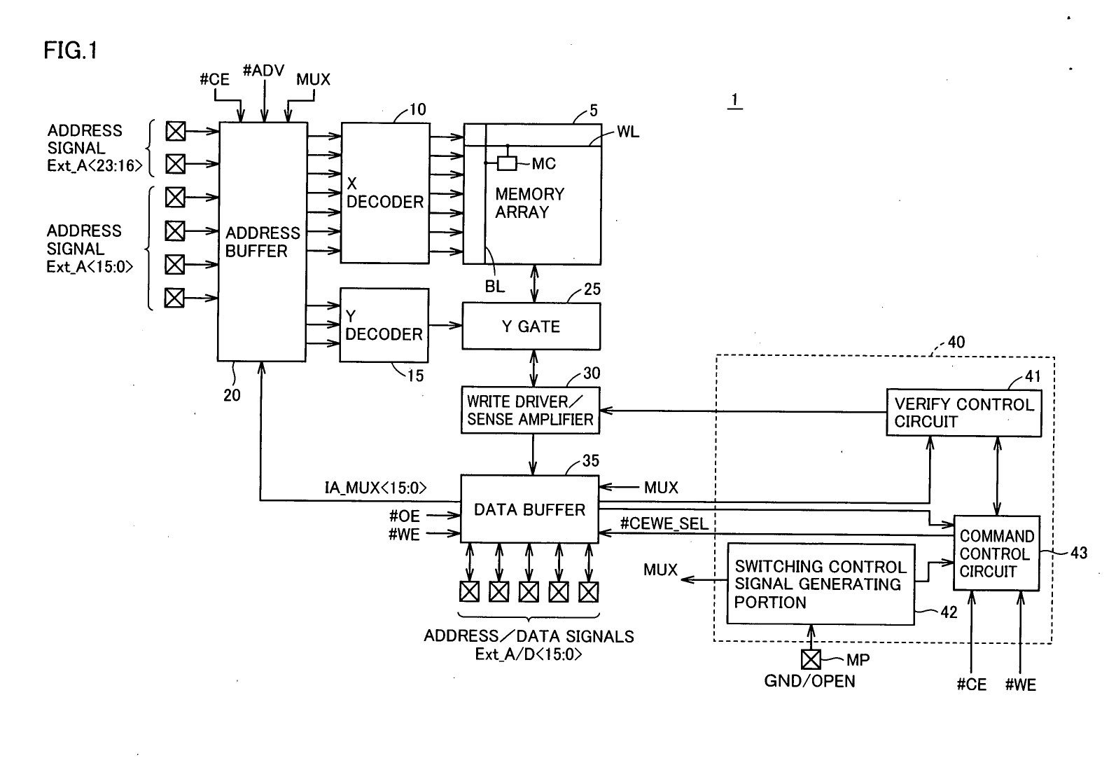

Referring to FIG. 1, a semiconductor memory device 1 according to an embodiment of the present invention includes: a memory array 5 having a plurality of memory cells MCs, not shown, integrally arranged in matrix; an X decoder 10 for activating a word line WL, which is provided to correspond to a memory cell row on a row side, based on an internal address signal from an address buffer 20; a Y gate 25 for controlling a connection between a bit line BL, which is provided to correspond to a memory cell column on a column side, and a write driver/sense amplifier 30; a Y decoder 15 for controlling the Y gate based on the internal address signal from address buffer 20; the address buffer 20 for generating the internal address signal based on an address signal input through an address pad (a terminal); a data buffer 35 for receiving inputs of address/data signals input through an address data multipad (a terminal) to buffer and output the same, or for receiving an input of a read data signal output from write driver/sense amplifier 30 to output the same to the address data multipad; and a control portion 40 for outputting a control signal and the like for controlling device 1. In the present embodiment, assume that the memory cell refers to the so-called flash memory. In FIG. 1, a single word line WL, a single bit line BL, and a single memory cell MC are illustrated as an example to show word lines provided to correspond to memory cell rows, bit lines provided to correspond to memory cell columns, and memory cells corresponding thereto.

Semiconductor memory device 1 according to the embodiment of the present invention has a function of switching between a non-multiplex method and a multiplex method. More particularly, semiconductor memory device 1 has the function of switching between a non-multiplex method (hereinafter also referred to as a non A/D-MUX mode) in which an address signal and a data signal are independently input into an address pad and a data pad, respectively, and a multiplex method (hereinafter also referred to as an A/D-MUX mode) in which an address signal and a data signal are input into the same, common multipad, namely, an address data multipad. In the present embodiment, an address signal Ext_A<23:0> is input, as an example, for address selection. In the present embodiment, assume that the symbol <x:0> indicates 0-x. Furthermore, a data signal to be processed has a data width of 16 bits, and is indicated as Ext_D<15:0>. Then an address signal Ext_A<15:0>, which has lower-order bits of address signal Ext_A<23:0>, and data signal Ext_D<15:0> are input through the same, common address data multipad. Assume that an address signal Ext_A<23:16>, which has higher-order bits of address signal Ext_A<23:0>, is input through a dedicated address pad. The bit widths of the address signal and the data signal are not limited thereto; the address signal and the data signal may have the same bit width. Alternatively, the present invention is applicable to the case where the data signal has a longer bit width than the address signal.

Data buffer 35 outputs the data signal input through the address data multipad to a verify control circuit 41 described below, in response to a control signal #WE.

Write driver/sense amplifier 30 writes data by driving a bit line via Y gate 25 at a level corresponding to a write data signal held by verify control circuit 41 during the data write. Furthermore, write driver/sense amplifier 30 senses a read data signal of a cell whose address is selected by X decoder 10 during the data read, and transmits the read data signal to data buffer 35.

Furthermore, data buffer 35 outputs the read data signal transmitted from write driver/sense amplifier 30, as a data signal, to the address data multipad in response to a control signal #OE. Data buffer 35 buffers address signal A<15:0> input into the address data multipad, and outputs the same as an internal address signal IA_MUX<15:0> to address buffer 20 in response to a switching control signal MUX.

Control circuit 40 includes verify control circuit 41 for controlling a verifying operation, data write, and the like, switching control signal generating circuit 42 for generating the switching control signal MUX (hereinafter simply referred to as the control signal MUX), and a command control circuit 43.

Verify control circuit 41 performs data write or data read based on the read data signal input via data buffer 35, or a verifying operation during data erasure. Verify control circuit 41 drives write driver/sense amplifier 30 as needed to perform an operation such as data rewrite. The data signal input through the address data multipad during data write is held by verify control circuit 41 via data buffer 35, and is output to write driver/sense amplifier 30 as a write data signal.

Command control circuit 43 outputs a control signal for specifying various operations upon receipt of an input of a control signal from the outside.

Address buffer 20 and data buffer 35 forms an interface circuit for sending and receiving an address signal and a data signal to and from the outside.

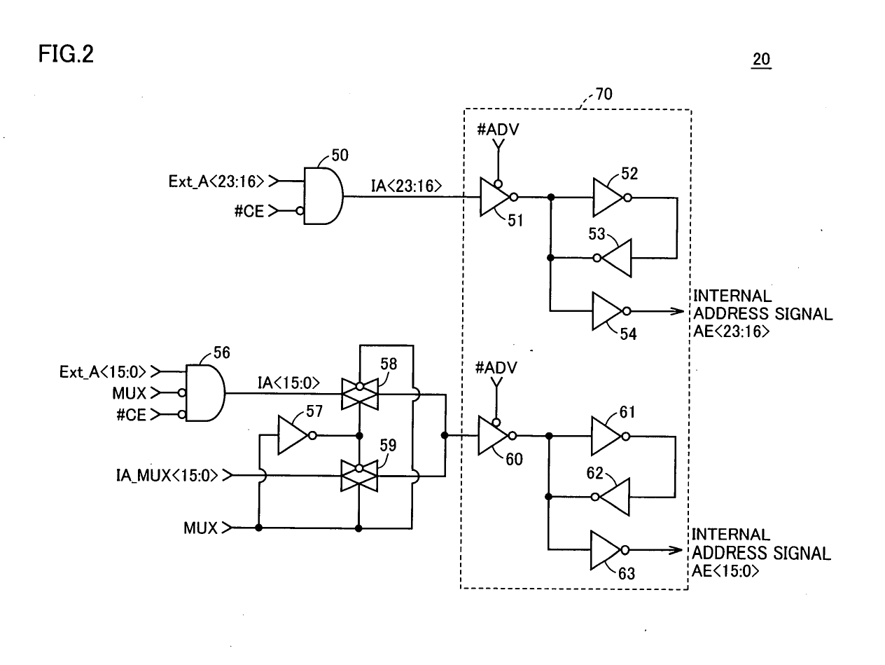

Referring to FIG. 2, address buffer 20 according to the first embodiment of the present invention includes logic circuits 50 and 56, an inverter 57, transfer gates 58 and 59, and a latch portion 70. Logic circuits 50 and 56 are AND circuits, as an example.

Logic circuit 50 receives inputs of address signal Ext_A<23:16> and a control signal #CE so that it is activated in response to control signal #CE (“L” level), and outputs address signal Ext_A<23:16> as an address signal IA<23:16>. In the case of control signal #CE (“H” level), all the bits of the address signal IA<23:16> are set to “0” (“L” level) without regard to address signal Ext_A<23:16>. In other words, all the bits of the address signal IA<23:16> are made invalid.

Logic circuit 56 receives inputs of Ext_A<15:0>, and control signals MUX and #CE so that it is activated in response to control signals MUX (“L” level) and #CE (“L” level), and outputs address signal Ext_A<15:0> as an address signal IA<15:0>.

Transfer gates 58 and 59 receive inputs of address signal IA<15:0> and IA_MUX<15:0>, respectively, and are complementarily activated in response to inputs of control signal MUX and a signal obtained by inverting control signal MUX by inverter 57. More particularly, if control signal MUX is at “L” level, transfer gate 58 is activated to transmit address signal IA<15:0> to latch portion 70. In contrast, if control signal MUX is at “H” level, transfer gate 59 is activated to transmit address signal IA_MUX<15:0> to latch portion 70. A signal path is switched by transfer gate 58 or 59 in accordance with control signal MUX.

Latch portion 70 includes inverters 51-54 and 60-63. Each of inverters 51 and 60 is activated in response to a control signal #ADV (“L” level), and inverts a signal input thereinto and outputs the same.

A signal output from inverter 51 is input into inverter 52. The signal inverted by inverter 52 is input into inverter 53. Inverter 53 then inverts the input signal and inputs the same into inverter 52 again. With this configuration, inverters 52 and 53 form a latch. The signal output from inverter 51 is latched in inverters 52 and 53, and the latched signal is inverted by inverter 54 to be output as an internal address signal AE<23:16>.

Inverters 60-63 have a configuration similar to that of inverters 51-54. Inverter 60 is activated in response to control signal #ADV (“L” level) and inverts a signal input thereinto and outputs the same. The signal latched in a latch formed of inverters 61 and 62 is inverted by inverter 63 to be output as an internal address signal AE<15:0>.

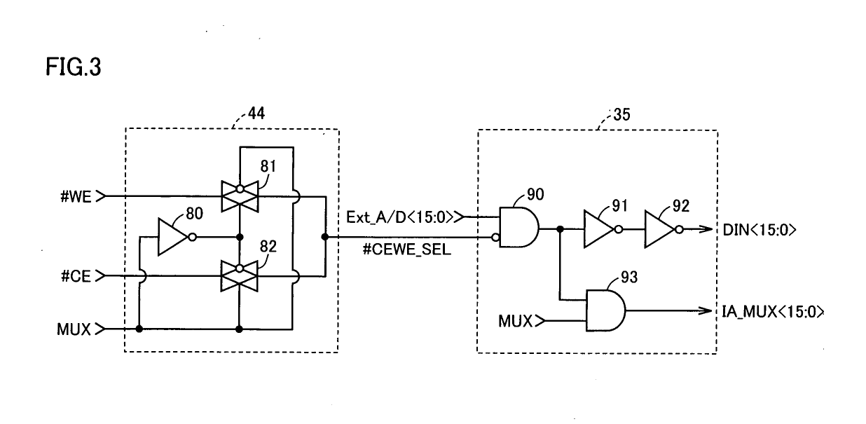

Referring to FIG. 3, a signal generating portion 44 and a part of the circuit of data buffer 35 in accordance with the first embodiment of the present invention will be described.

The case in which signal generating portion 44 is included in command control circuit 43 will be described as an example, although it is not limited thereto. For example, it is also possible to adopt a configuration in which signal generating portion 44 is included in data buffer 35.

Signal generating portion 44 receives inputs of control signals #WE, #CE and MUX to output a control signal #CEWE_SEL.

Data buffer 35 receives inputs of Ext_A/D<15:0> and control signals #CEWE_SEL and MUX, to buffer the same to output a write data signal DIN or address signal IA_MUX<15:0>.

Signal generating portion 44 includes transfer gates 81 and 82, and an inverter 80. Transfer gates 81 and 82 receive inputs of control signals #WE and #CE, respectively, and are complementarily activated based on control signal MUX and a signal obtained by inverting control signal MUX by inverter 80. More particularly, if control signal MUX is at “L” level, transfer gate 81 is activated, and control signal #WE is output as control signal #CEWE_SEL. In contrast, if control signal MUX is at “H” level, transfer gate 82 is activated, and control signal #CE is output as control signal #CEWE_SEL.

Data buffer 35 includes logic circuits 90 and 93 and inverters 91 and 92. In the present embodiment, assume that each of logic circuits 90 and 93 is an AND circuit.

Logic circuit 90 receives inputs of address/data signals Ext_A/D<15:0> and control signal #CEWE_SEL so that it is activated in response to the input of control signal #CEWE_SEL (“L” level), and outputs Ext_A/D<15:0> to each of input nodes of inverters 91 and 92 and logic circuit 93. Inverters 91 and 92 receive a signal from logic circuit 90 to output a write data signal DIN<15:0>. Write data signal DIN<15:0> is output to write driver/sense amplifier 30 via verify control circuit 41.

In contrast, logic circuit 93 receives an output signal of logic circuit 90 and control signal MUX so that it is activated in response to control signal MUX (“H” level), and outputs address signal IAMUX<15:0>.

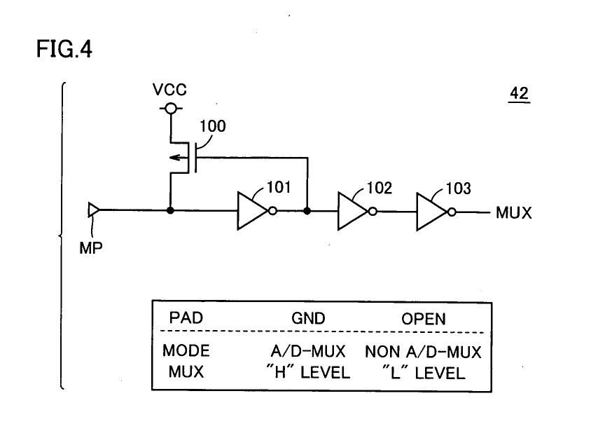

Referring to FIG. 4, switching control signal generating circuit 42 according to the first embodiment of the present invention includes a transistor 100 and inverters 101-103.

Transistor 100 has a source connected to a power supply voltage VCC (“H” level), a drain electrically coupled to a mode pad MP, and a gate electrically coupled to an output node of inverter 101. An output signal of inverter 101 is output through inverters 102 and 103 as control signal MUX. Assume that transistor 100 is a P-channel MOS transistor.

Here, control signal MUX in this circuit is considered. If mode pad MP is connected to a ground voltage GND (“L” level), an output signal of inverter 101 is set to “H” level. Accordingly, transistor 100 is turned off and control signal MUX is output as “H” level. In contrast, if mode pad MP is opened, an output signal of inverter 101 is set to “L” level. Accordingly, transistor 100 is turned on, which causes power supply voltage VCC (“H” level) to be electrically coupled to an input node of inverter 101, and the input node of the inverter is fixed to “L” level. Therefore, control signal MUX is output as “L” level.

Based on the above-described configuration, it is possible to switch between a non-multiplex method in which an address signal and a data signal are independently input into an address pad and a data pad, respectively, and a multiplex method in which an address signal and a data signal are input into the same, common multipad, namely, the address data multipad.

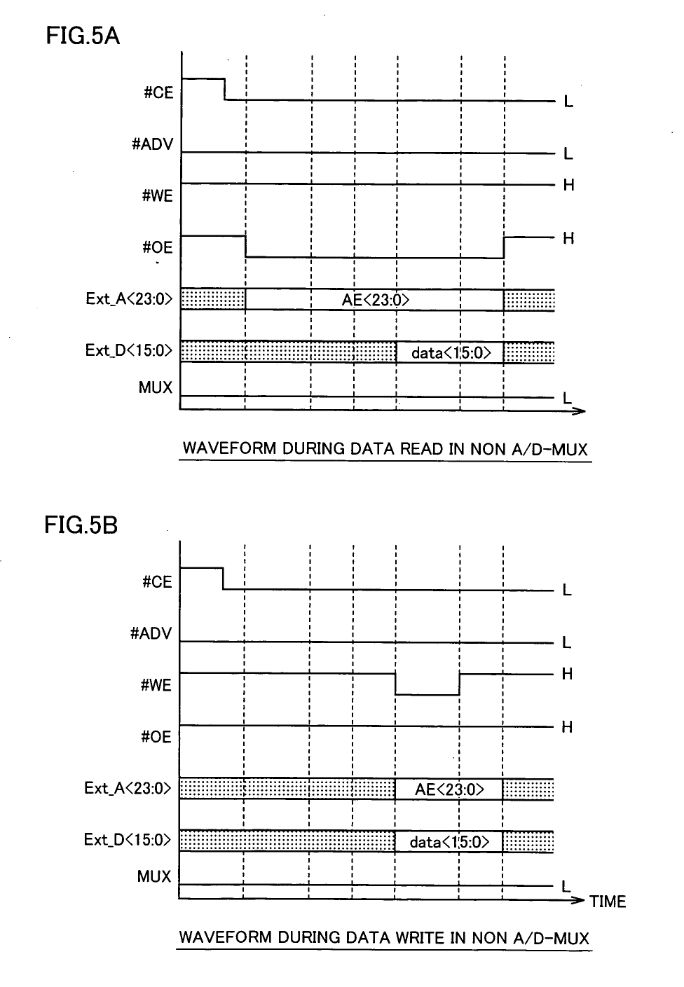

Referring to FIG. 5A, a waveform diagram during data read in the non A/D-MUX mode will be described.

Referring to FIG. 5A, as control signal #CE is turned to “L” level, the entire device is activated. In the non A/D-MUX mode, control signal MUX is at “L” level, transfer gate 58 in address buffer 20 is turned on, and the address signal is input only through the address pad. In other words, the address signal is not input from data buffer 35, and the address data multipad is used only for a data signal.

In reading data, address signal Ext_A<23:0> is input into the address pad.

Accordingly, X decoder 10 selects an address in memory cell array 5 in accordance with the input address signal to select a memory cell, from which a stored read data signal is output.

In reading data, as described above, a sense amplifier, in particular, in write driver/sense amplifier 30 operates and performs sensing. Data buffer 35 then outputs a signal incoming from write driver/sense amplifier 30, as a read data signal data <15:0>, to the address data multipad in response to control signal #OE (“L” level).

Referring to FIG. 5B, a waveform diagram during data write in the non A/D-MUX mode will be described.

Referring to FIG. 5B, as control signal #CE is turned to “L” level, the entire device is activated. In the non A/D-MUX mode, control signal MUX is at “L” level, transfer gate 58 in address buffer 20 is turned on, and the address signal is input only through the address pad.

In other words, the address signal is not input from data buffer 35, and the address data multipad is used only for a data signal.

In writing data, address signal Ext_A<23:0> is input into the address pad, and data signal data <15:0> is input into the address data multipad.

In writing data, control signal #WE is set to “L” level. Here, in command control circuit 43, control signal #WE is output to data buffer 35 as control signal #CEWE_SEL in response to control signal MUX (“L” level). Data buffer 35 receives data signal data <15:0> based on an input of control signal #WE (“L” level), and outputs the received data signal to verify control circuit 41. Verify control circuit 41 outputs the received signal as write data signals DIN<15:0> to write driver/sense amplifier 30. A write driver, in particular, in write driver/sense amplifier 30 drives a bit line at a prescribed logic level based on write data signal DIN<15:0>.

In contrast, X decoder 10 selects an address in the memory cell array in accordance with the address signal input in a manner similar to the above-described manner to select a memory cell, into which data is written.

Accordingly, in writing data in the non A/D-MUX mode, an address signal and a data signal can be input in parallel for operation.

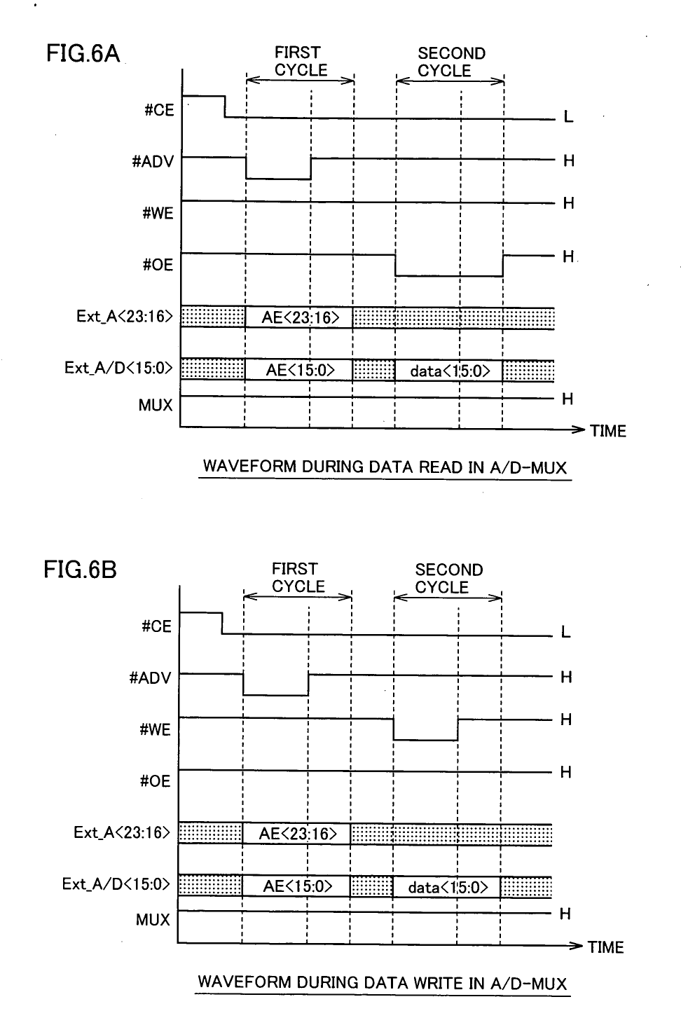

Referring to FIG. 6A, a waveform diagram during data read in the A/D-MUX mode will be described.

Referring to FIG. 6A, as control signal #CE is turned to “L” level, the entire device is activated. In the A/D-MUX mode, control signal MUX is at “H” level, transfer gate 59 in address buffer 20 is turned on, and address signal Ext_A<15:0> having lower-order bits is input through the address data multipad. In other words, the address signal is also input from data buffer 35 to address buffer 20, and the address signal as well as data signal is input together into the address data multipad.

Initially, in reading data in the first cycle, address signal Ext_A<23:0> is input into the address pad and the address data multipad. More particularly, address signal Ext_A<23:16> having higher-order bits of address signal Ext_A<23:0> is input through the address pad, while address signal Ext_A<15:0> having lower-order bits of address signal Ext_A<23:0> is input through the address data multipad.

Since control signal #ADV is at “L” level, the input address signals are latched. In conjunction with this, X decoder 10 selects an address in memory cell array 5 in accordance with the input address signals to select a memory cell.

In reading data in the second cycle, the stored read data signal is output from the selected memory cell, and as described above, a sense amplifier, in particular, in write driver/sense amplifier 30 performs sensing. Data buffer 35 then responds to control signal #OE (“L” level) and outputs a signal incoming from write driver/sense amplifier 30, as read data signal data<15:0>, to the address data multipad.

Referring to FIG. 6B, a waveform diagram during data write in the A/D-MUX mode will be described.

Referring to FIG. 6B, as control signal #CE is made to “L” level, the entire device is activated. In the A/D-MUX mode, control signal MUX is at “H” level, transfer gate 59 in address buffer 20 is turned on, and address signal Ext_A<15:0> having lower-order bits is input through the address data multipad. In other words, the address signal is also input from data buffer 35 to address buffer 20, and the address signal as well as the data signal is input together into the address data multipad.

In writing data in the first cycle, address signal Ext_A<23:0> is input into the address pad and the address data multipad. More particularly, address signal Ext_A<23:16> having higher-order bits of address signal Ext_A<23:0> is input through the address pad, while address signal Ext_A<15:0> having lower-order bits of address signal Ext_A<23:0> is input through the address data multipad.

Since control signal #ADV is at “L” level, the input address signals are latched. In conjunction with this, X decoder 10 selects an address in memory cell array 5 in accordance with the input address signals to select a memory cell.

In writing data in the second cycle, data signal data<15:0> is input into the address data multipad. Here, in command control circuit 43, control signal #CE is output as control signal #CEWE_SEL to data buffer 35. Data buffer 35 receives data signal data<15:0> based on an input of control signal #CE (“L” level), and outputs the received data signal to verify control circuit 41. Verify control circuit 41 outputs the received input signal, as write data signal DIN<15:0>, to write driver/sense amplifier 30. A write driver, in particular, in write driver/sense amplifier 30, drives a bit line at a prescribed logic level based on write data signal DIN<15:0>.

In conjunction with this, data is written into the selected memory cell.

In the A/D-MUX mode, an address signal as well as a data signal is input together into the address data multipad. Therefore, operations performed beyond the latch portion, for example, a data write operation, a data read operation and the like are performed in a manner similar to that in the non A/D-MUX mode. However, inputs generated before the address signals are latched in the latch portion, for example, are required to be input in serial, unlike the non A/D-MUX mode, because an address signal and a data signal cannot be input in parallel. Therefore, it is necessary to modify an external command system.

A semiconductor memory device having a function operating in the A/D-MUX mode according to the first embodiment of the present invention interrupts the input of the address signal through the address data multipad in accordance with control signal MUX and switches the signal paths such that the address signal is input through the address pad.

Accordingly, an address signal and a data signal can be input in parallel, which makes it possible to switch from the A/D-MUX mode to the non A/D-MUX mode.

In the conventional configuration, a semiconductor memory device having a function of operating in the A/D-MUX mode is required to use a dedicated tester owing to its function.

In this respect, various tests are conducted as a wafer test using a tester. Thereafter, for example, a voltage trimming of an internal power supply of a chip, remedy of defective memory cells deviating from a property criterion, or rejection of a defective chip is performed. More particularly, a tester conducts a test in accordance with wide variety of several hundreds of test patterns. For example, a tester writes data into a memory cell, erases data from a memory cell, and others.

In the A/D-MUX mode, as described above, an address signal and a data signal are input into the common pad. Therefore, if data is to be written, for example, these signals are required to be input in serial, and all the test patterns that pertain to the address input and the data input are required to be modified into patterns different from those used in the non A/D-MUX mode. In addition, increment of an address for serial input of an address signal and a data signal, and generation of a pattern for physically checking the data must be performed alternately. The configuration of the pattern also becomes extremely complicated.

Accordingly, the tester corresponding to the A/D-MUX mode requires an extremely complicated test pattern when compared with the tester corresponding to the non A/D-MUX mode, which results in increase in cost required for the test.

In the semiconductor memory device according to the first embodiment, it is possible to use a tester employed in the conventionally-popular non A/D-MUX mode, namely, in a configuration where an address pad and a data pad are separated from each other, to perform a memory test. In other words, even in the semiconductor memory device having a function of operating in the A/D-MUX mode, it is possible to perform a memory test designed for the non A/D-MUX mode. Therefore, there is no need for providing a new test program or a new test jig, and there is no need for imposing an additional constraint to the test. Accordingly, a conventionally-used, general-purpose tester can be utilized to conduct a low-cost test and reduce the cost required for the test.

### Second Embodiment

In the first embodiment above, there has been described a method in which control signal MUX is generated depending on whether the pad is connected to ground voltage GND or is left open.

In the second embodiment, generation of another control signal MUX will be described.

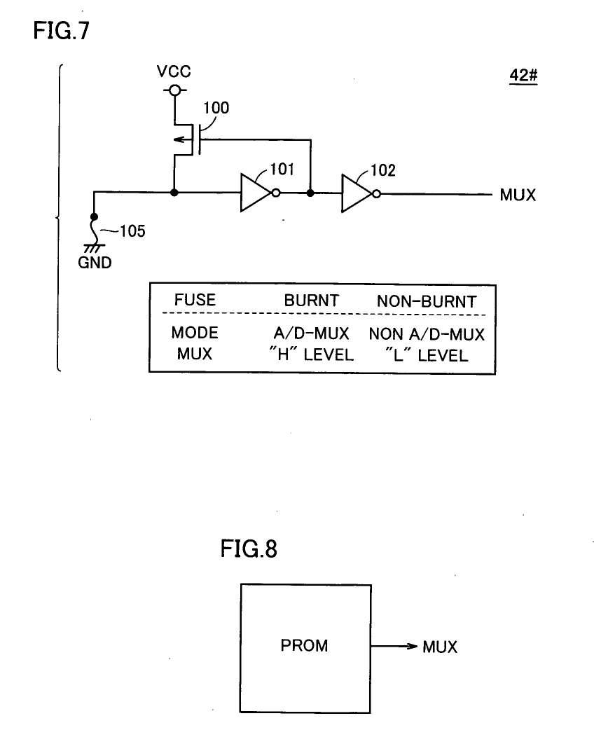

Referring to FIG. 7, a switching control signal generating circuit 42# according to the second embodiment of the present invention is similar to the switching control signal generating circuit 42 described in FIG. 4, except that a fuse 105 connected to ground voltage GND instead of mode pad MP is provided, and that inverter 103 is not used. The other configurations are similar to those of the switching control signal generating circuit 42 described in FIG. 4, and thus the detailed description thereof will not be repeated.

Fuse 105 has its one end connected to ground voltage GND, and the other end connected to an input node of inverter 101. Assume that fuse 105 can be burnt with laser trimming and others.

For example, if fuse 105 is not burnt, control signal MUX is set to “L” level, namely, to the non A/D-MUX mode. In contrast, if fuse 105 is burnt, the input node of inverter 101 is made open, and thereafter, transistor 100 is turned on and control signal MUX is set to “H” level, namely, to the A/D-MUX mode.

Accordingly, it is possible to switch between the A/D-MUX mode and the non A/D-MUX mode, based on the burnt/non-burnt state of fuse 105.

Furthermore, still another method will be described.

After the test using a tester was conducted, in order to provide voltage trimming of an internal power supply of a chip or to remedy defective memory cells deviating from a property criterion, information for remedying such memory cells and others is usually stored in a storage area of a Programmable Read Only Memory (PROM), for example, located in the semiconductor memory device. When the power is supplied, this information is automatically read for use in an operation of the semiconductor memory device.

Referring to FIG. 8, a PROM embedded in the semiconductor memory device according to the second embodiment of the present invention stores, in advance, information about the A/D-MUX mode/non A/D-MUX mode described in the embodiments of the present invention. It is also possible to allow control signal MUX (“H” level/“L” level) to be automatically output from the PROM when power is supplied.

In accordance with the logic level of control signal MUX, it is possible to switch between the A/D-MUX mode and the non A/D-MUX mode. Accordingly, it is possible to easily modify a design according to the user's demand.

In the present embodiment, a flash memory is taken as an example of a memory cell. However, a memory cell is not limited thereto. The present invention is also applicable to other various types of memory cells, such as a Dynamic Random Access Memory (DRAM) cell and a Static Random Access Memory (SRAM) cell.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device according to the present invention, comprising:
a memory array having a plurality of memory cells integrally arranged in matrix;
an interface circuit for sending and receiving a signal to and from an outside;
a multipad used in sending and receiving an output and an input of each of an address signal and a data signal between said interface circuit and the outside in a first mode;
an address selection circuit for accessing a selected memory cell in said memory array based on the address signal input into said interface circuit; and
an address pad having said address signal input thereinto in a second mode independently of said multipad, wherein
said interface circuit includes a switching circuit for connecting said multipad and said address selection circuit in said first mode, and connecting said address pad and said address selection circuit in said second mode.

2. The semiconductor memory device according to claim 1, further comprising:
a mode pad which can be brought into one of a connected state and a disconnected state with respect to a prescribed voltage, and
a signal generating circuit connected to said mode pad for generating a control signal specifying one of said first mode and said second mode based on one of the connected state and the disconnected state into which said mode pad is brought with respect to said prescribed voltage, wherein
said switching circuit switches connections based on said control signal.

3. The semiconductor memory device according to claim 1, further comprising a write control circuit for performing data write on the selected memory cell accessed based on said data signal which has been input, wherein
said interface circuit further includes a buffer circuit for transmitting said data signal input through said multipad to said write control circuit in response to an input of a control signal which specifies said data write.

4. The semiconductor memory device according to claim 1, wherein said address signal and said data signal are input into said multipad in a time-sharing manner in said first mode.

5. The semiconductor memory device according to claim 1, further comprising a storing portion for outputting information stored in advance, in response to a prescribed instruction, wherein
said switching circuit switches connections based on said information output from said storing portion.

6. The semiconductor memory device according to claim 5, wherein
said storing portion has a fuse element which can be brought into one of a burnt state and a non-burnt state, and
said switching circuit switches connections in response to said prescribed instruction and in accordance with information based on one of the burnt state and the non-burnt state of said fuse element.
